(19) United States
(12) Patent Application Publication
(10) Pub. No.: US 2020/0075439 A1
(43) Pub. Date: Mar. 5, 2020

(54) SEMICONDUCTOR DEVICE AND MANUFACTURING METHOD OF SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Kazuhiro WATANABE, Suginami Tokyo (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 16/277,566

(22) Filed: Feb. 15, 2019

(30) Foreign Application Priority Data
Sep. 5, 2018 (JP) 2018-166347

(51) Int. Cl. H01L 23/13; H01L 23/31; H01L 21/56; H01L 25/18; H01L 23/00

(52) U.S. Cl. CPC H01L 23/13; H01L 23/3157; H01L 24/81; H01L 25/18; H01L 24/17; H01L 21/563

(57) ABSTRACT

According to one embodiment, a semiconductor device includes a mounting board having a first surface on which a plurality of semiconductor chips is mounted. The first surface of the mounting board is provided with a frame that encloses peripheries of the plurality of semiconductor chips, and the frame is to be filled with filler. The mounting board has a second surface that is opposite to the first surface, and a plurality of connection terminals is formed on the second surface.

### CROSS-REFERENCE TO RELATED APPLICATIONS

This application is based upon and claims the benefit of priority from Japanese Patent Application No. 2018-166347, filed on Sep. 5, 2018; the entire contents of which are incorporated herein by reference.

### FIELD

The embodiments described herein relate generally to a semiconductor device and a manufacturing method of the semiconductor device.

### BACKGROUND

Conventionally, there has been disclosed a technology for placing a frame on a board on which a semiconductor chip is mounted, and filling the frame with underfill resin, so as to protect and reinforce connection terminals formed on the semiconductor chip. Recently, there has been developed a multichip module (MCM) obtained by integrating a plurality of semiconductor chips in order to provide multi functions to the semiconductor device. The plurality of semiconductor chips is mounted on the MCM, and thus miniaturization may be an issue, so that there is desired a semiconductor device that is capable of realizing miniaturization as well as protection and reinforcement using underfill resin.

### BRIEF DESCRIPTION OF THE DRAWINGS

FIGS. 1A to 1C are diagrams illustrating a semiconductor device according to a first embodiment;

FIGS. 2A to 2C are diagrams illustrating a semiconductor device according to a second embodiment;

FIGS. 3A to 3C are diagrams illustrating a semiconductor device according to a third embodiment;

FIGS. 4A to 4G are diagrams illustrating processes according to one embodiment of a manufacturing method of the semiconductor device according to the third embodiment;

FIGS. 5A to 5G are plan views illustrating the processes of the manufacturing method corresponding to those illustrated in FIGS. 4A to 4G;

FIGS. 6A to 6C are diagrams illustrating a semiconductor device according to a fifth embodiment;

FIGS. 7A to 7H are diagrams illustrating processes according to one embodiment of a manufacturing method of the semiconductor device according to the fifth embodiment;

FIGS. 8A to 8H are plan views illustrating the processes of the manufacturing method corresponding to those illustrated in FIGS. 7A to 7H;

FIGS. 9A to 9C are diagrams illustrating a semiconductor device according to a seventh embodiment; and

FIGS. 10A to 100 are diagrams illustrating a semiconductor device according to an eighth embodiment.

### DETAILED DESCRIPTION

In general, according to one embodiment, a semiconductor device includes a plurality of semiconductor chips each of which has a surface on which a plurality of connection terminals is formed. The semiconductor device includes a mounting board that has a first surface on which the plurality of semiconductor chips is mounted by using the plurality of connection terminals. The semiconductor device includes a frame that is seamlessly formed on the first surface of the mounting board, the frame enclosing the plurality of semiconductor chips. The semiconductor device includes a filler that fills the frame. The semiconductor device includes a plurality of connection terminals that is formed on a second surface of the mounting board. The second surface is opposite to the first surface.

Exemplary embodiments of a semiconductor device and a manufacturing method of the semiconductor device will be explained below in detail with reference to the accompanying drawings. The present disclosure is not limited to the following embodiments.

### First Embodiment

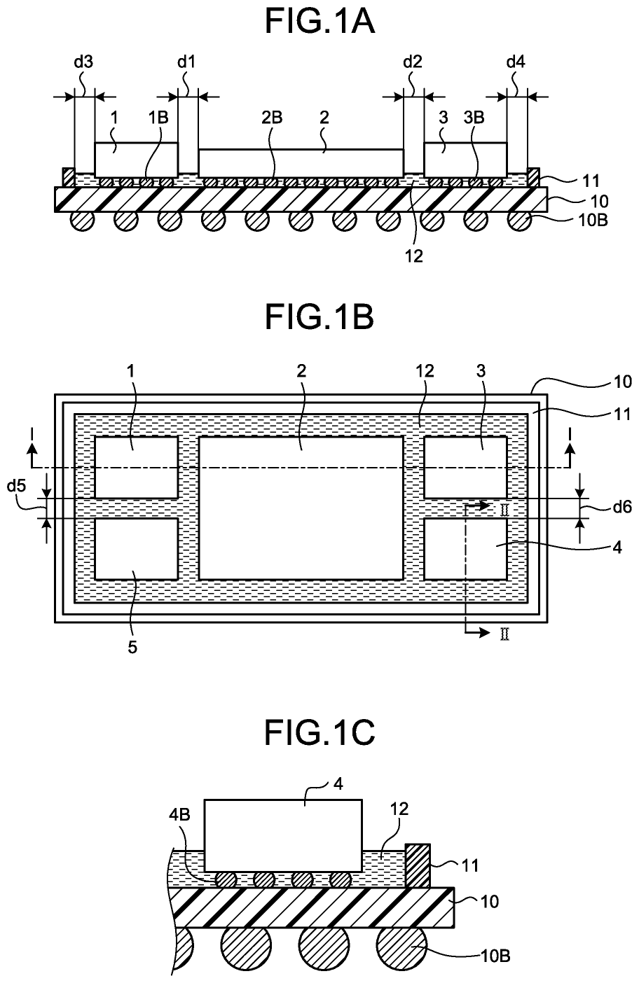

FIGS. 1A to 10 are diagrams illustrating a semiconductor device according to a first embodiment. FIG. 1A is a schematic cross-sectional view illustrating a structure taken along a dashed line I-I illustrated in FIG. 1B. FIG. 10 is a schematic cross-sectional view illustrating an enlarged structure taken along a dashed line II-II illustrated in FIG. 1B. The semiconductor device according to the present embodiment includes a plurality of semiconductor chips 1 to 5. For example, the semiconductor chip 2 has arithmetic processing function, and each of the semiconductor chips 1 and 3 to 5 has memory function. The semiconductor chips 1 to 5 constitute, as it is called, a multichip module.

A plurality of connection terminals is formed on a surface of each of the semiconductor chips 1 to 5. In FIGS. 1A to 10, connection terminals 1B to 4B of the semiconductor chips 1 to 4 are illustrated. The connection terminals 1B to 4B are constituted of solder bumps and/or Cu pillars, for example. The semiconductor chips 1 to 5 are mounted, with the use of flip chip bonding, on a mounting board 10 by the connection terminals.

The mounting board 10 is made of, for example, glass fabric base epoxy resin laminates, as it is called, epoxy glass. The mounting board 10 includes a frame 11 on its surface. The frame 11 is simultaneously formed when the mounting board 10 is formed, for example. The frame 11 may be formed by using a solder mask that is formed on the surface of the mounting board 10.

A region enclosed by the frame 11 is filled with filler 12. For example, thermosetting epoxy resin may be used as the filler 12. The filler 12 protects and reinforces the connection terminals that are connected with the mounting board 10 and that are formed on reverse faces of the semiconductor chips 1 to 5.

A plurality of connection terminals 10B, constituted of solder balls, is formed in a grid on a reverse face of the mounting board 10, for example. The connection terminals formed on the semiconductor chips 1 to 5 and the connection terminals 10B formed on the mounting board 10 are connected by using wires (not illustrated) formed in the mounting board 10. The reverse-face connection terminals 10B connect the semiconductor device to a printed board (not illustrated), for example.

In the present embodiment, the semiconductor chips 1 to 5 are enclosed by the one frame 11. The filler 12, which fills the frame 11, protects and reinforces the connection terminals formed on the semiconductor chips 1 to 5. An interval between the semiconductor chips and that between the frame and each of the semiconductor chips are reduced, so that it is possible to reduce an area of the mounting board 10. In other words, it is possible to miniaturize the semiconductor device on which the plurality of semiconductor chips is mounted. When a distance between the semiconductor chips is reduced, distances of the wires (not illustrated) formed in the mounting board 10 are able to be reduced, for example. Thus, a transmission time interval of a signal between the semiconductor chips is able to be reduced, so that it is possible to increase a processing speed of the semiconductor device.

The filler 12 may be put in from a gap between the semiconductor chip and the frame 11 after the semiconductor chip has been mounted on a region enclosed by the frame 11.

### Second Embodiment

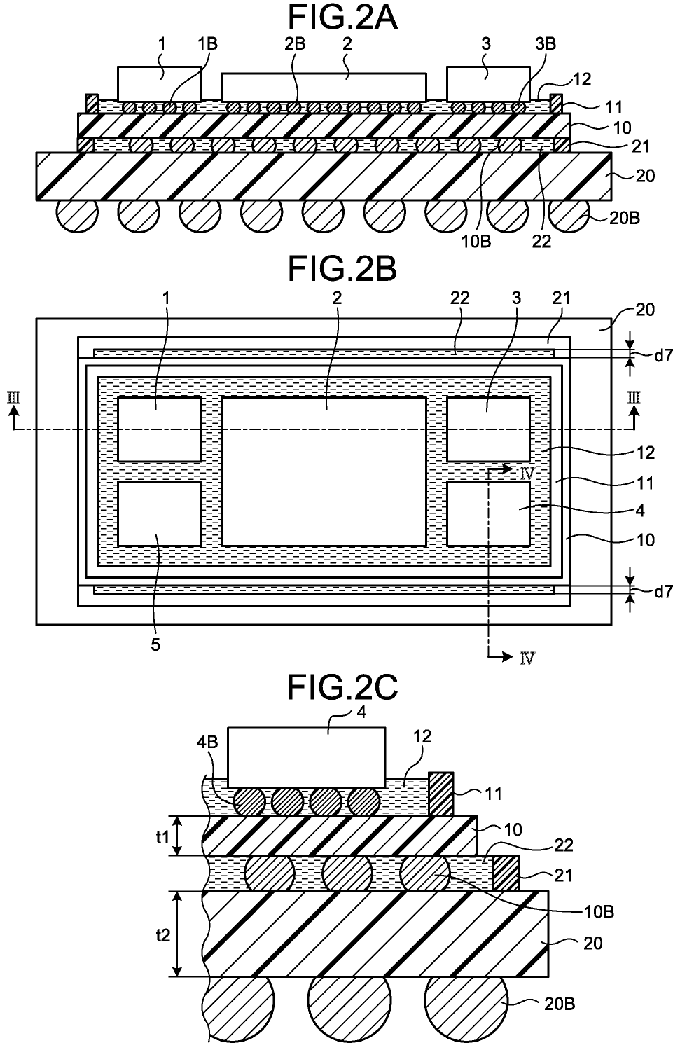

FIGS. 2A to 2C are diagrams illustrating a semiconductor device according to a second embodiment. Note that in the following, a part different from the above-mentioned embodiment will be mainly described, and the common parts are represented with the same symbols and the description is omitted appropriately. The same applies hereinafter. The semiconductor device according to the present embodiment includes a mounting board 20. The mounting board 20 includes a frame 21 on its surface. As illustrated in FIG. 2B, the frame 21 has a shape in which a right side and a left side of the frame 21 individually coincide with an outer periphery of the mounting board 10, and an upper side and a lower side individually extend so as to leave respective gaps d7, for example. In other words, the frame 21 is in contact with the reverse face of the mounting board 10 on the right side and the left side of the frame 21. The frame 21 is simultaneously formed when the mounting board 20 is formed. The frame 21 may be formed by using a solder mask that is formed on the surface of the mounting board 20. The above-mentioned “coincide with” includes a case of “substantially coincide with”, and the same applies hereinafter.

A value of a linear expansion coefficient of the mounting board 20 is adjusted to be larger than that of the mounting board 10, for example. When a value of a linear expansion coefficient of the mounting board 10 is adjusted to be approximately “10” (ppm/° C.), for example, that of the mounting board 20 is adjusted to be approximately “20” (ppm/° C.). Linear expansion coefficients of the semiconductor chips 1 to 5 are approximately “3” (ppm/° C.), for example. Therefore, the linear expansion coefficient is set so as to increase from the semiconductor chips toward the mounting board 20, and thus it is possible to ease effects of the stress on the semiconductor chips due to a temperature rise of a device (not illustrated) on which the semiconductor device is mounted.

A thickness t2 of the mounting board 20 may be larger than a thickness t1 of the mounting board 10. Assume that the thickness t2 of the mounting board 20 is “0.6” (mm) and the thickness t1 of the mounting board 10 is “0.4” (mm), for example. The increase in the thickness t2 of the mounting board 20 improves the rigidity of the mounting board 20; and thus the tolerance for the stress, in mounting the semiconductor device, is improved; so that it is possible to improve the reliability of the semiconductor device.

The frame 21 extends beyond the outer periphery of the mounting board 10 so as to form the gaps d7, and filler 22 is able to be put in through any of the gaps d7.

The connection terminals formed on the semiconductor chips are protected and reinforced by the filler 12 that is put into the frame 11, and the connection terminals 10B are protected and reinforced by the filler 22 that is put into the frame 21.

According to the present embodiment, when the linear expansion coefficients of the mounting boards 10 and 20 are adjusted, it is possible to ease effects of the stress on the semiconductor chips due to a temperature rise of a device on which the semiconductor device is mounted. A value of the linear expansion coefficient of the mounting board 20 may be similar to that of the mounting board 10. By employing a multi-layer structure including the mounting boards 10 and 20, it is possible to ease effects of the stress on the semiconductor chips 1 to 5 due to a temperature rise.

### Third Embodiment

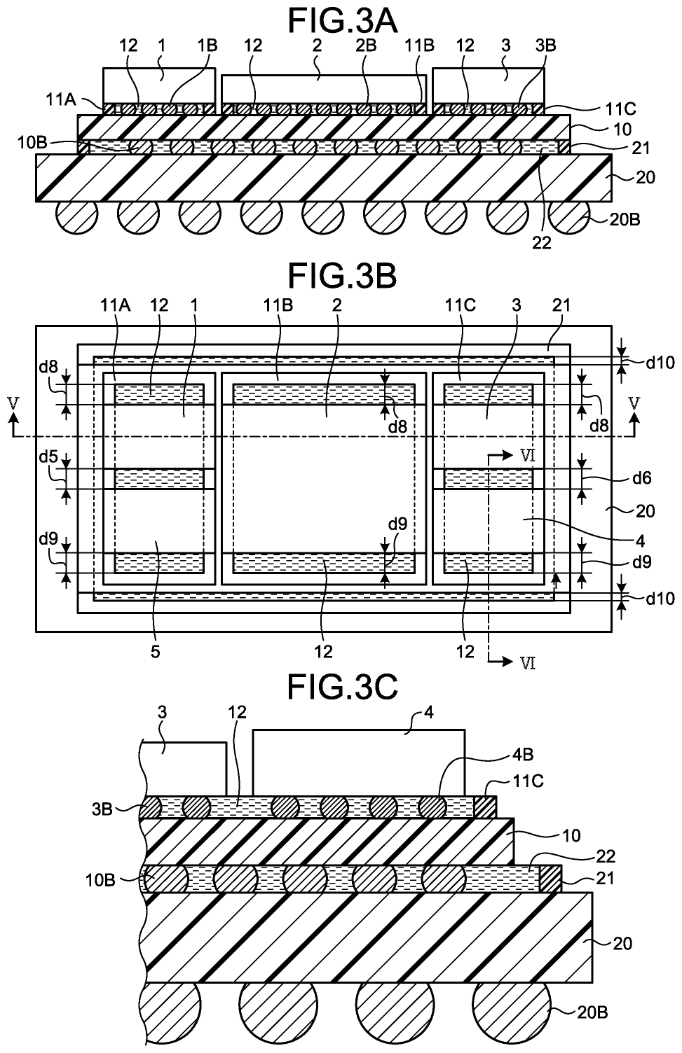

FIGS. 3A to 3C are diagrams illustrating a semiconductor device according to a third embodiment. FIG. 3A is a schematic cross-sectional view illustrating a structure taken along a dashed line V-V illustrated in FIG. 3B. FIG. 3C is a schematic cross-sectional view illustrating an enlarged structure taken along a dashed line VI-VI illustrated in FIG. 3B. The semiconductor device according to the present embodiment includes, on a surface of the mounting board 10: a frame 11A that is provided so as to correspond to the semiconductor chips 1 and 5; a frame 11B that is provided so as to correspond to the semiconductor chip 2; and a frame 11C that is provided so as to correspond to the semiconductor chips 3 and 4. In other words, as illustrated in FIG. 3B, the frame 11A coincides with profiles on left sides and right sides of the semiconductor chips 1 and 5, extends so as to form a gap d8 on an upper side of the semiconductor chip 1, and extends so as to form a gap d9 on an lower side of the semiconductor chip 5. The frame 11A is in contact with reverse faces of the semiconductor chips 1 and 5 on left sides and right sides of the semiconductor chips 1 and 5. A gap d5 is formed between the semiconductor chips 1 and 5, and a gap d6 is formed between the semiconductor chips 3 and 4.

Similarly, the frame 11B coincides with profiles on a left side and a right side of the semiconductor chip 2, extends so as to form the gap d8 on an upper side of the semiconductor chip 2, and extends so as to form the gap d9 on an lower side of the semiconductor chip 2. The frame 11B is in contact with a reverse face of the semiconductor chip 2 on a left side and a right side of the semiconductor chip 2.

The frame 11C coincides with profiles on left sides and right sides of the semiconductor chips 3 and 4, extends so as to form the gap d8 on an upper side of the semiconductor chip 3, and extends so as to form the gap d9 on an lower side of the semiconductor chip 4. The frame 11C is in contact with reverse faces of the semiconductor chips 3 and 4 on left sides and right sides of the semiconductor chips 3 and 4. The filler 12 is put into each of the frames 11A to 11C so as to protect and reinforce the connection terminals formed on the semiconductor chips 1 to 5.

The mounting board 20 includes the frame 21 on its surface. As illustrated in FIG. 3B, a shape of the frame 21 coincides, in accordance with a profile of the mounting board 10, with the profile of the mounting board 10 on a right side and a left side of the mounting board 10, and extends so as to form gaps d10 on an upper side and a lower side of the mounting board 10, for example. The frame 21 is in contact with the reverse face of the mounting board 10 on a left side and a right side of the frame 21. The frame 21 is simultaneously formed when the mounting board 20 is formed. The frame 21 may be formed by using a solder mask that is formed on the surface of the mounting board 20.

The connection terminals formed on the semiconductor chips are protected and reinforced by the filler 12, furthermore, a portion of reverse faces of the semiconductor chips are in contact with and held by the frames 11A to 11C, so that the semiconductor chips are mounted on the mounting board 10 in a stable state. Moreover, the reverse faces of the semiconductor chips are in contact with the frames 11A to 11C, so that it is possible to prevent the filler 12 from flowing out of the frames 11A to 11C.

The filler 12 may be put in from the gaps between the semiconductor chips and the frame 11A to 11C after the semiconductor chips have been mounted on the mounting board 10. Or the semiconductor chips 1 to 5 may be mounted on the surface of the mounting board 10 after the filler 12 has been put in. The filler 22 are able to be put in from the gap d10.

In the present embodiment, the connection terminals formed on the semiconductor chips are protected and reinforced by the filler 12 filling the frames 11A to 11C formed on the mounting board 10. The portions of reverse faces of the semiconductor chips are in contact with and held by the frames 11A to 11C, so that the semiconductor chips are mounted on the mounting board 10 in a stable state. Moreover, the portions of the reverse faces of the semiconductor chips are in contact with the frames 11A to 11C, so that it is possible to prevent the filler 12 from flowing out of the frames 11A to 11C. The connection terminals 10B are protected and reinforced by the filler 22. Similarly to the second embodiment, when linear expansion coefficients of the mounting boards 10 and 20 are adjusted, it is possible to ease effects of the stress on the semiconductor chips due to a temperature rise of a device on which the semiconductor device is mounted.

### Fourth Embodiment

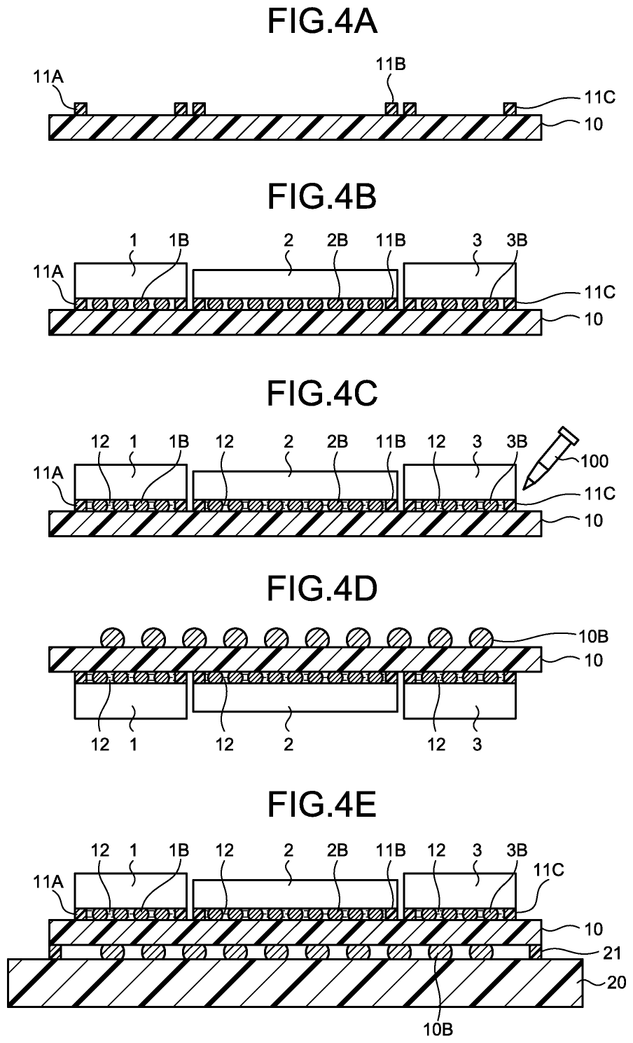

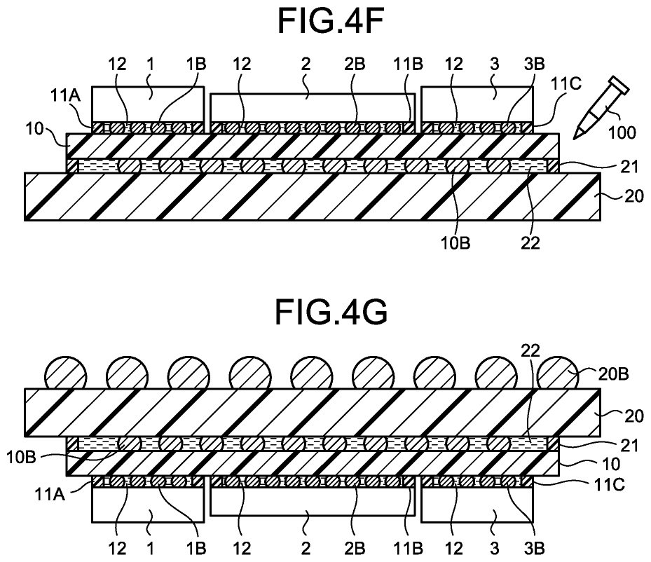

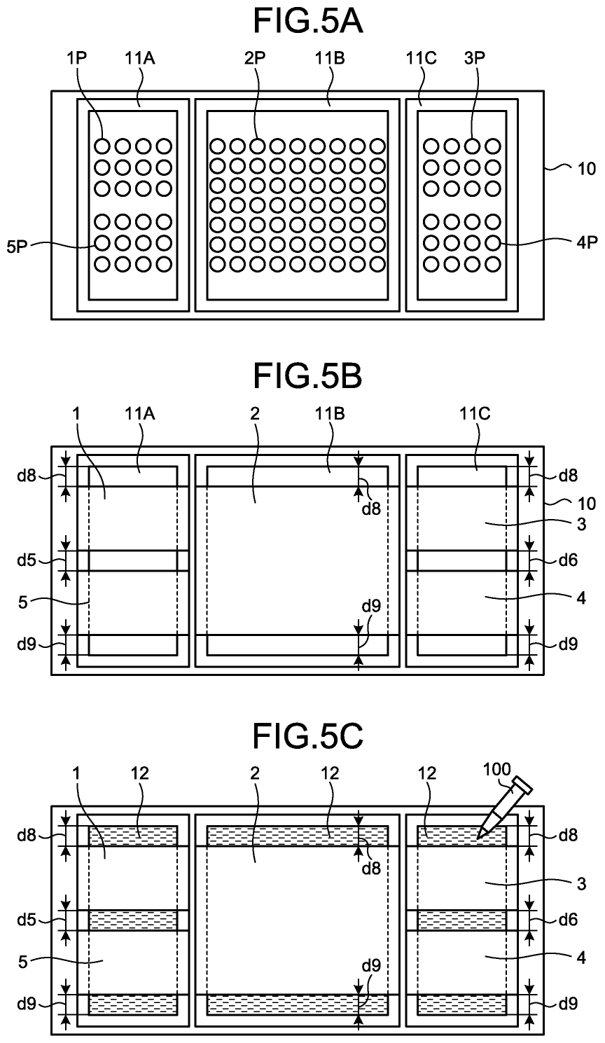

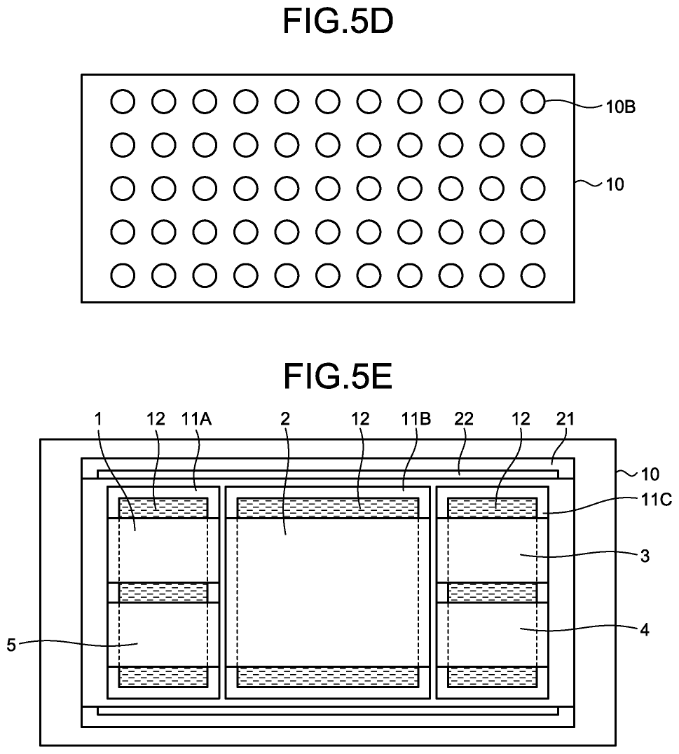

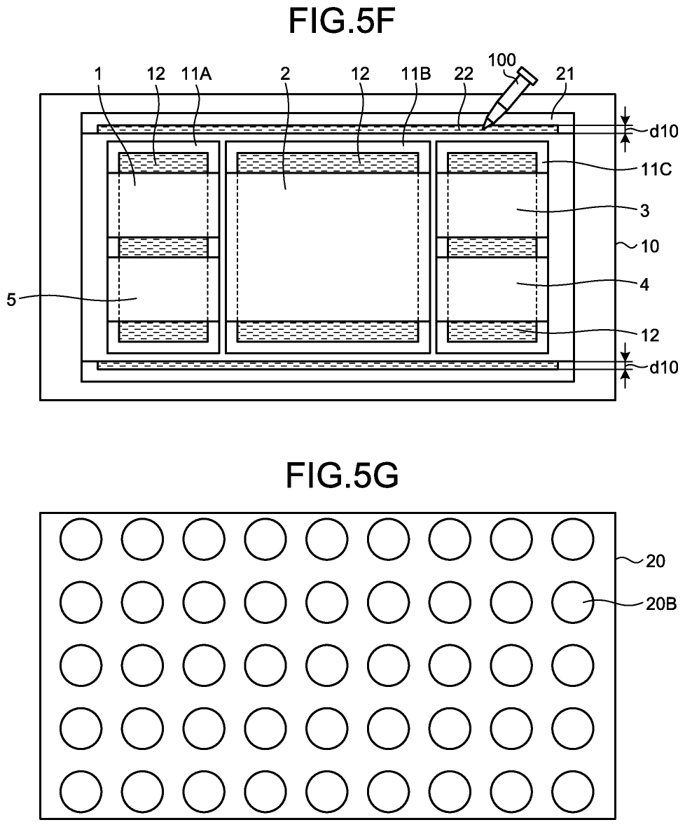

FIGS. 4A to 4G are cross-sectional views illustrating one embodiment of a manufacturing method of the semiconductor device according to the third embodiment, and FIGS. 5A to 5G are plan views illustrating the manufacturing method corresponding to FIGS. 4A to 4G. Hereinafter, FIGS. 4A to 4G will be explained in association with FIGS. 5A to 5G.

First, the mounting board 10, on which the frames 11A to 11C are formed, is prepared (see FIGS. 4A and 5A). The frames 11A to 11C are formed so as to correspond to the semiconductor chips that are to be mounted. On the surface of the mounting board 10, conductive connecting pads 1P to 5P are formed with which the connection terminals of the semiconductor chips are to be connected.

Next, the semiconductor chips 1 to 5 are prepared, and each of them is mounted on a corresponding part of the surface of the mounting board 10 (see FIGS. 4B and 5B). For example, the connection terminals, which are constituted of solder balls, and the connecting pads 1P to 5P are bonded together by using heat treatment, and thus the semiconductor chips 1 to 5 are mounted on the surface of the mounting board 10 so that the gaps d8 and d9 are formed between the frames 11A to 11C and upper sides and lower sides of the semiconductor chips 1 to 3, the gap d5 is formed between the semiconductor chips 1 and 5, and the gap d6 is formed between the semiconductor chips 3 and 4.

Next, the frames 11A to 11C are filled with the filler 12 that is constituted of, for example, thermosetting epoxy resin by using a supply device 100 (see FIGS. 4C and 5C). The filler 12 may be put in from any of the gaps d5, d6, d8, and d9. The filler 12 is cured by using thermal treatment after the frames 11A to 11C have been filled.

The connection terminals 10B, which are constituted of, for example, solder balls, are formed in a grid on the reverse face of the mounting board 10 (see FIGS. 4D and 5D).

The mounting board 10 is mounted on the mounting board 20, on which the frame 21 is formed, so as to form the gaps d10 on an upper side and a lower side of the frame 21 (see FIGS. 4E and 5E). The connection terminals 10B and the connecting pads (not illustrated), which are formed on the surface of the mounting board 20, are bonded together by using heat treatment so as to mount the mounting board 10 on the mounting board 20, for example.

Next, the filler 22 is put into the frame 21 (see FIGS. 4F and 5F). For example, the filler 22, which is constituted of thermosetting epoxy resin, may be put in by using the supply device 100. The filler 22 is put in from the gap d10. The filler 22 is cured by using thermal treatment after the frame 21 has been filled with the filler 22.

For example, connection terminals 20B, which are constituted of solder balls, are formed in a grid on a reverse face of the mounting board 20 (FIGS. 4G and 5G). Thus, a semiconductor device with which the plurality of semiconductor chips 1 to 5 is integrated is completed. For example, a curing temperature of the epoxy resin is lower than a melting temperature of the solder ball. Thus, the fillers 12 and 22 are able to be cured without affecting, due to temperature processing for curing the fillers 12 and 22, connection states between the connection terminals 1B to 5B and the mounting board 10 and between the connection terminals 10B and the mounting board 20.

### Fifth Embodiment

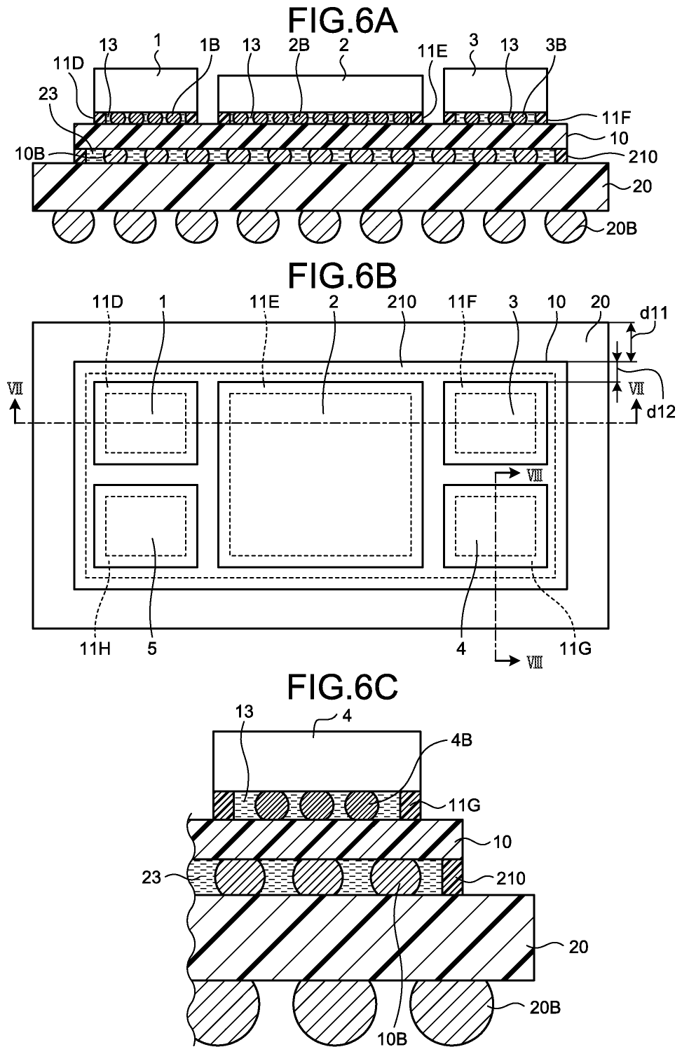

FIGS. 6A to 6C are diagrams illustrating a semiconductor device according to a fifth embodiment. FIG. 6A is a schematic cross-sectional view illustrating a structure taken along a dashed line VII-VII illustrated in FIG. 6B. FIG. 6C is a schematic cross-sectional view illustrating an enlarged structure taken along a dashed line VIII-VIII illustrated in FIG. 6B. The semiconductor device according to the present embodiment includes, on the surface of the mounting board 10, frames 11D to 11H having shapes that respectively coincide with profiles of the semiconductor chips 1 to 5. In other words, a profile of the frame 11D has a shape that coincides with the profile of the semiconductor chip 1. Similarly, the frames 11E to 11H have shapes that respectively coincide with the profiles of the semiconductor chips 2 to 5. The frames 11D to 11H are formed in accordance with respective outer-peripheral shapes of the semiconductor chips 1 to 5, on which the connection terminals are formed, so as to be in seamlessly contact with reverse faces of the semiconductor chips 1 to 5.

A frame 210, which is formed on the surface of the mounting board 20, has a shape that is seamlessly formed in accordance with an outer-peripheral shape of the mounting board 10. In other words, the frame 210 is in seamlessly contact with an outer-peripheral portion of the mounting board 10.

For example, thermoplastic acrylic resin is employed as fillers 13 and 23 for filling the frames 11D to 11H and the frame 210. A manufacturing method using the thermoplastic fillers 13 and 23 will be mentioned later.

According to the present embodiment, the connection terminals formed on the semiconductor chips 1 to 5 are protected and reinforced by the filler 13 filling the frames 11D to 11H. The frames 11D to 11H are in seamlessly contact with reverse faces of the respective semiconductor chips 1 to 5 so as to stably hold the semiconductor chips, and thus the semiconductor chips 1 to 5 are mounted on the mounting board 10 in stable state. Moreover, the reverse faces of the semiconductor chips 1 to 5 are in seamlessly contact with the respective frames 11D to 11H, so that it is possible to prevent the filler 13 from flowing out of the frames 11D to 11H.

The frames 11D to 11H respectively coincide with outer-peripheral shapes of the semiconductor chips 1 to 5, and a shape of the frame 21 coincides with the outer-peripheral shape of the mounting board 10. In other words, there is provided no gap, and thus a distance d11 between outer peripheries of the mounting boards 10 and 20 and a distance d12 between outer peripheries of the semiconductor chip 3 and the mounting board 10 are able to be reduced. Thus, areas of the mounting boards 10 and 20 are able to be reduced, so that it is possible to miniaturize the semiconductor device. The frame 210 is in seamlessly contact with the reverse face of the mounting board 10 so as to hold the mounting board 10. Thus, the connection terminals 10B are protected and reinforced by the filler 23, furthermore, the mounting board 10 is supported by the frame 210 and is mounted on the mounting board 20 in a stable state.

### Sixth Embodiment

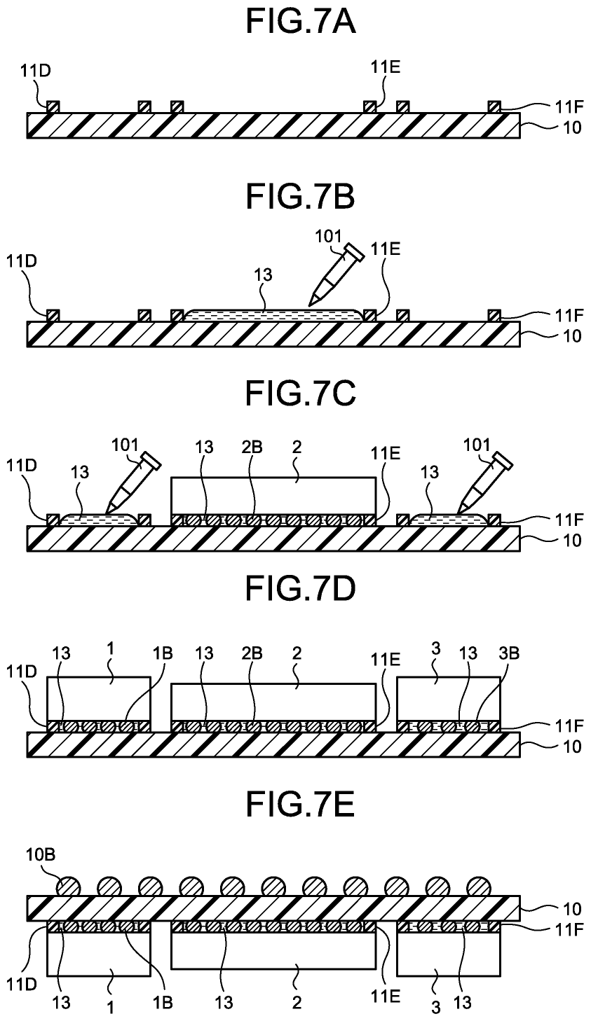

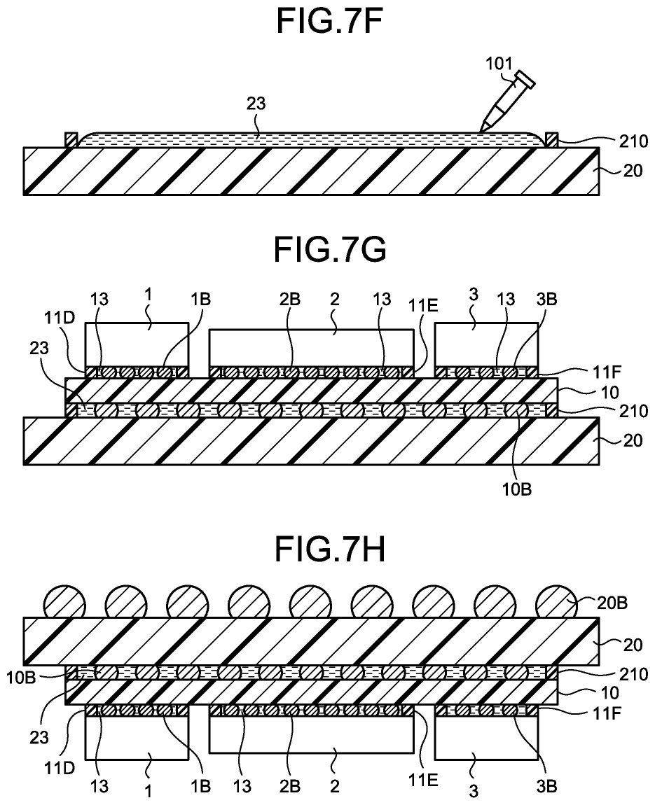

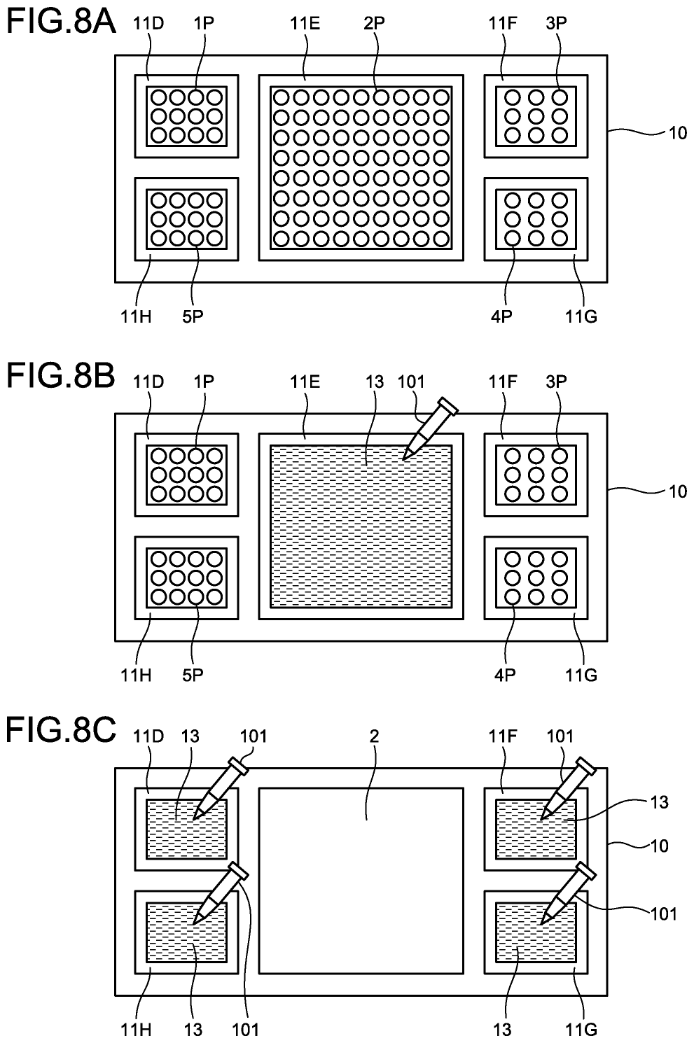

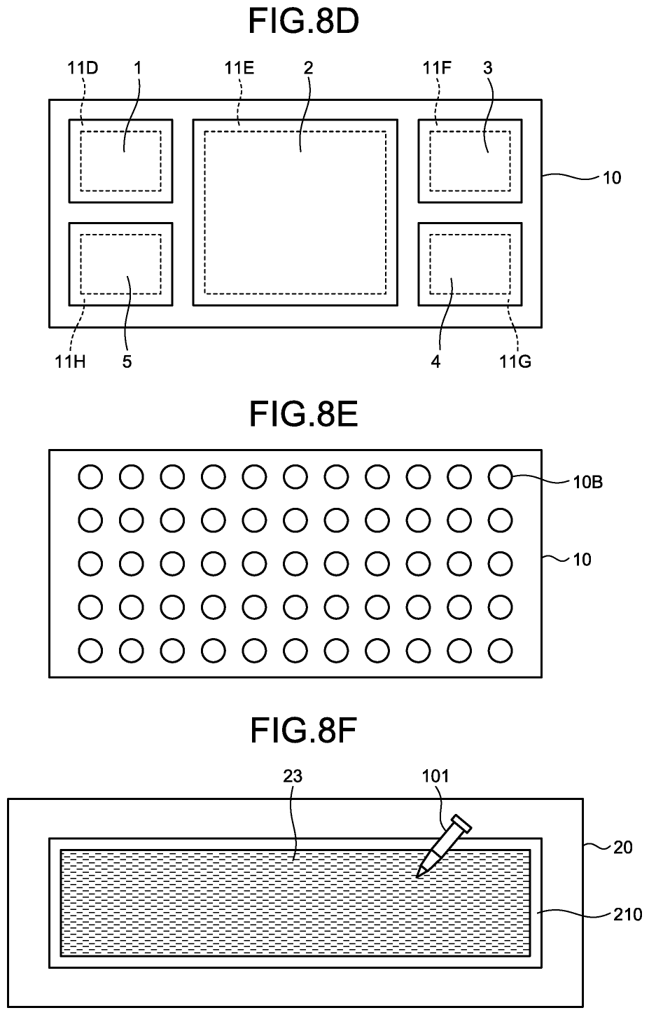

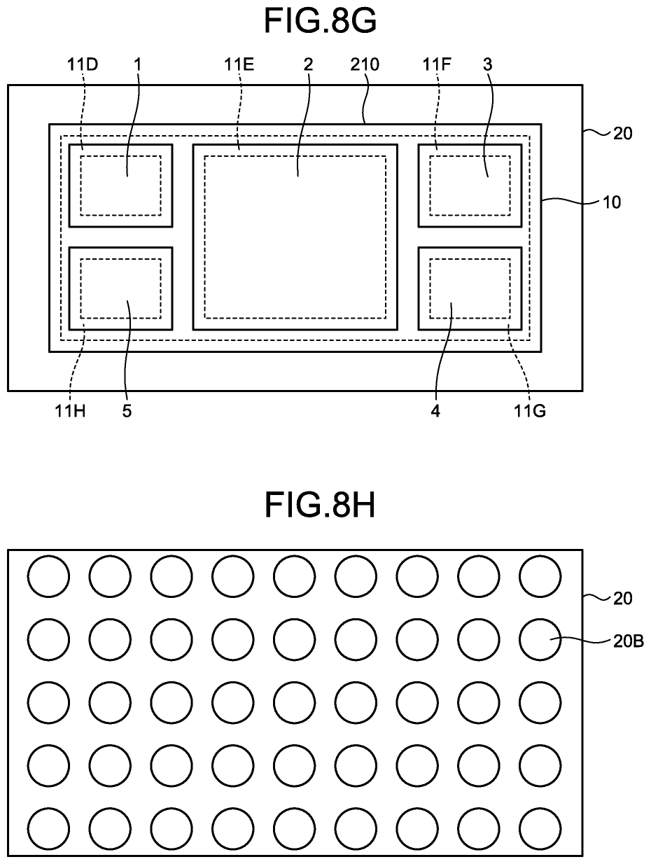

FIGS. 7A to 7H are schematic cross-sectional views illustrating one embodiment of a manufacturing method of a semiconductor device according to the fifth embodiment, and FIGS. 8A to 8H are plan views illustrating the manufacturing method corresponding to that illustrated in FIGS. 7A to 7H. Hereinafter, FIGS. 7A to 7H will be explained in association with FIGS. 8A to 8H.

First, the mounting board 10, on which the frames 11D to 11H are formed, is prepared (see FIGS. 7A and 8A). The frames 11D to 11H are formed so as to correspond to the semiconductor chips that are to be mounted. On the surface of the mounting board 10, connecting pads 1P to 5P are formed with which the connection terminals of the semiconductor chips are to be connected.

Next, frame 11E is filled with the filler 13 that is constituted of, for example, thermoplastic acrylic resin by using a supply device 101 (see FIGS. 7B and 8B). The semiconductor chip 2 is mounted on the frame 11E that is filled with the filler 13 (see FIGS. 7C and 8C). For example, the connection terminals 2B, which are constituted of solder balls, and the connecting pad 2P, which is formed on the surface of the mounting board 10, are bonded together by using heat treatment, and thus the semiconductor chip 2 is mounted on the surface of the mounting board 10.

A melting temperature of the connection terminals 2B is higher than that of the thermoplastic acrylic resin. Therefore, the filler 13 is melted in the thermal treatment for connecting the connection terminals 2B with the connecting pad 2P, so that it is possible to bond the connection terminals 2B and the connecting pad 2P together in a state where the connection terminals 2B are in contact with the connecting pad 2P.

Next, the filler 13 is put into the frames 11D, 11F, 11G, and 11H by using the supply device 101. The semiconductor chips 1, 3, 4, and 5 are respectively mounted on the frames 11D, 11F, 11G, and 11H that are filled with the filler 13 (FIGS. 7D and 8D). For example, the connection terminals 1B, 3B, 4B, and 5B are respectively bonded to the connecting pads 1P, 3P, 4P, and 5P by using the thermal treatment so as to mount the semiconductor chips 1, 3, 4, and 5 on the mounting board 10.

The connection terminals 10B, which are constituted of, for example, solder balls, are formed in a grid on the reverse face of the mounting board 10 (see FIGS. 7E and 8E).

Next, the filler 23, which is constituted of thermoplastic acrylic resin, for example, is put into the frame 210 formed on the mounting board 20 by using the supply device 101 (FIGS. 7F and 8F).

The mounting board 10, on which the semiconductor chips 1 to 5 are mounted, is mounted on the mounting board 20, on which the frame 210 filled with the filler 23 is formed (FIGS. 7G and 8G). For example, the connection terminals 10B and a connecting pad (not illustrated), which is formed on the surface of the mounting board 20, are bonded together by using heat treatment, and thus the mounting board 10 is mounted on the mounting board 20.

The connection terminals 20B, which are constituted of, for example, solder balls, are formed in a grid on the reverse face of the mounting board 20 (see FIGS. 7H and 8H). Thus, a semiconductor device with which the plurality of semiconductor chips 1 to 5 is integrated is completed.

By employing the manufacturing method according to the present embodiment, it is possible to provide a semiconductor device having a structure for protecting and reinforcing the connection terminals, which are formed on the semiconductor chips 1 to 5 and the mounting board 10, by using the fillers 13 and 23 filling the frames 11D to 11H and 210. Each of the frames 11D to 11H has a structure for being seamlessly contact with an outer-peripheral portion of the corresponding semiconductor chip to support the corresponding semiconductor, so that it is possible to mount the semiconductor chips on the mounting board 10 in a stable state. Moreover, the semiconductor chips 1 to 5 are respectively mounted on the frames 11D to 11H in a state where the reverse faces of the semiconductor chips 1 to 5 are in seamlessly contact with the frames 11D to 11H, so that it is possible to manufacture the semiconductor device while preventing the filler 13 from flowing out of the frames 1DA to 1DH.

### Seventh Embodiment

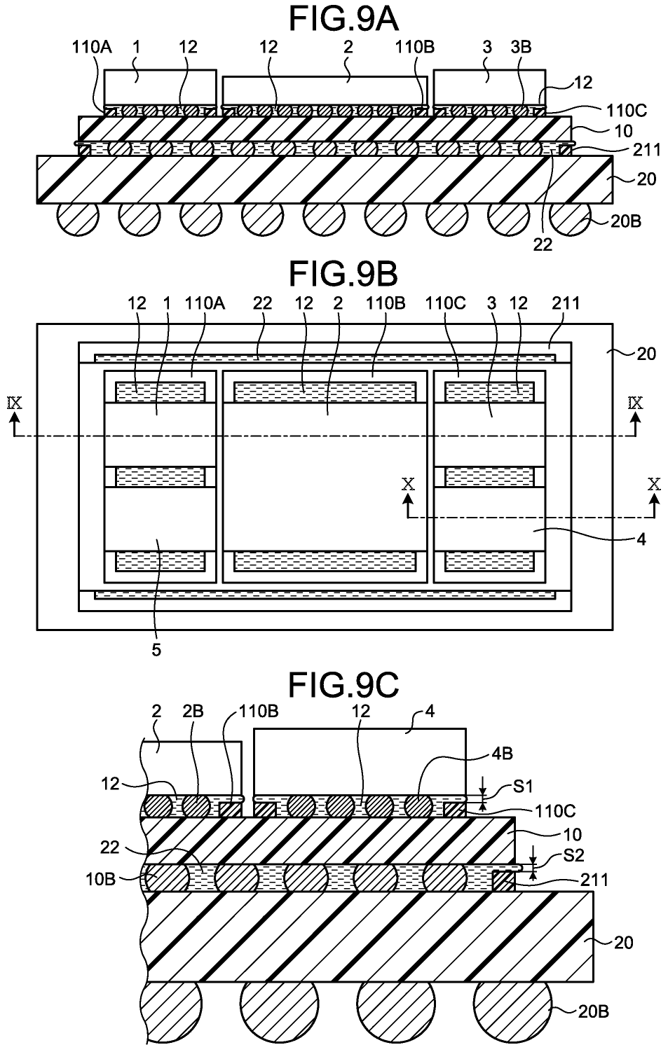

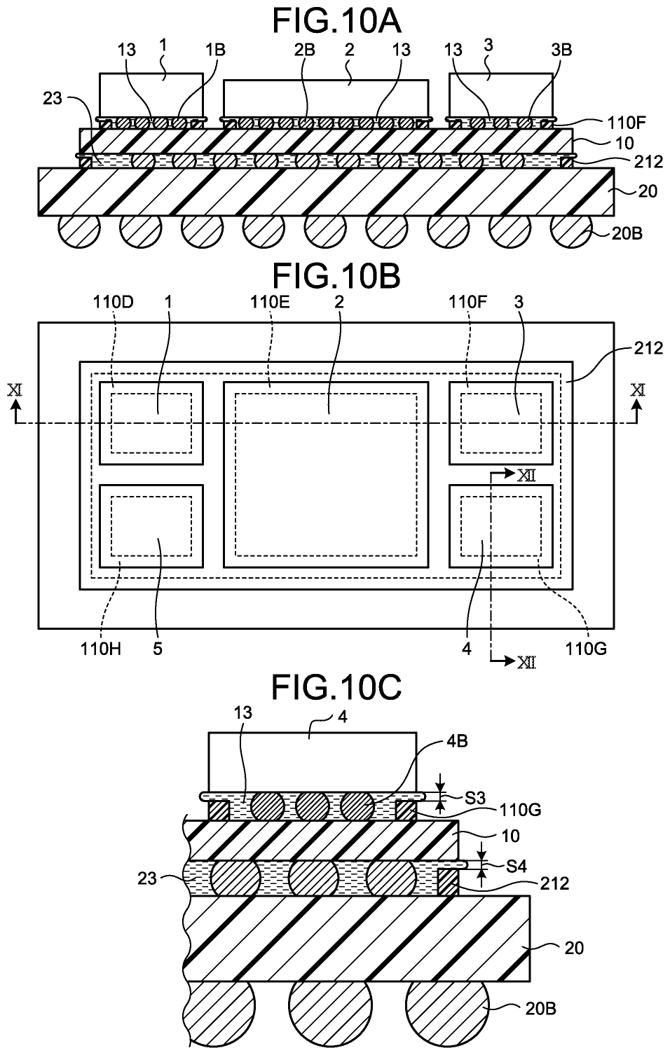

FIGS. 9A to 9C are diagrams illustrating a semiconductor device according to a seventh embodiment. FIG. 9A is a schematic cross-sectional view illustrating a structure taken along a dashed line IX-IX illustrated in FIG. 9B. FIG. 9C is a schematic cross-sectional view illustrating an enlarged structure taken along a dashed line X-X illustrated in FIG. 9B. In the present embodiment, as illustrated in FIG. 9C, a gap S1 is arranged between a frame 110C, which is formed on the mounting board 10, and a reverse face of the semiconductor chip 4. Similarly, a gap S2 is arranged between the mounting board 10 and an upper portion of a frame 211 that is formed on the mounting board 20. Thus, the fillers 12 and 22, respectively being put into the frames 110C and 211, flow into the gaps S1 and S2 so as to fill the gaps S1 and S2. A similar gap is arranged between each of the semiconductor chips 1, 2, 3, and 5 and corresponding one of frames 110A, 110B, and 110C.

According to the present embodiment, the filler 12 protects and reinforces the connection terminals formed on the semiconductor chips. The semiconductor chips 1 to 5 are held by the filler 12 that fills the gap S1. Thus, it is possible to mount the semiconductor chips 1 to 5 on the mounting board 10 in a stable state.

The mounting board 10 is held by the filler 22 that fills the gap S2. Thus, it is possible to mount the mounting board 10 on the mounting board 20 in a stable state. The gap S1 between the frames 110A to 110C and the semiconductor chips 1 to 5, and the gap S2 between the frame 211 and the mounting board 10 are respectively filled with the fillers 12 and 22, and thus the control over heights of the frames 110A to 110C and 211 may be comparatively rough, thereby leading to facilitation of the manufacturing.

### Eighth Embodiment

FIGS. 10A to 100 are diagrams illustrating a semiconductor device according to an eighth embodiment. FIG. 10A is a schematic cross-sectional view illustrating a structure taken along a dashed line XI-XI illustrated in FIG. 10B. FIG. 100 is a schematic cross-sectional view illustrating an enlarged structure taken along a dashed line XII-XII illustrated in FIG. 10B.

As illustrated in FIG. 10B, the surface of the mounting board 10 according to the present embodiment includes frames 110D to 110H, each of which has a shape that coincides with a profile of corresponding one of the semiconductor chips 1 to 5. In other words, a profile of the frame 110D has a shape that coincides with the profile of the semiconductor chip 1. Similarly, each of the frames 110E to 110H has a shape that coincides with the profile of corresponding one of the semiconductor chips 2 to 5. A frame 212 is formed on the mounting board 20, and has a shape that is seamlessly formed in accordance with the outer-peripheral shape of the mounting board 10.

As illustrated in FIG. 100, a gap S3 is arranged between an upper surface of the frame 110G and the semiconductor chip 4. Similarly, gaps are arranged between upper surfaces of the frames 110D to 11H and the semiconductor chips 1 to 5. A gap S4 is arranged between the frame 212 and the mounting board 10. Thus, the fillers 13 and 23, having been put into the frame 110D to 110H and 212, respectively flow into the gaps S3 and S4 so as to fill the gaps S3 and S4.

According to the present embodiment, the filler 13 protects and reinforces the connection terminals. The semiconductor chips 1 to 5 are held by the filler 13 that fills the gap S3. Thus, it is possible to mount the semiconductor chips 1 to 5 on the mounting board 10 in a stable state.

The mounting board 10 is held by the filler 23 that fills the gap S4. Thus, it is possible to mount the mounting board 10 on the mounting board 20 in a stable state. The gaps S3 and S4 are respectively filled with the fillers 13 and 23, and thus the control over heights of the frames 110D to 110H and 212 may be comparatively rough, thereby leading to facilitation of the manufacturing.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a plurality of semiconductor chips each of which has a surface on which a plurality of connection terminals is formed;
a mounting board that has a first surface on which the plurality of semiconductor chips is mounted by using the plurality of connection terminals;
a frame that is seamlessly formed on the first surface of the mounting board, the frame enclosing the plurality of semiconductor chips;
a filler that fills the frame; and
a plurality of connection terminals that is formed on a second surface of the mounting board, the second surface being opposite to the first surface.

2. The semiconductor device according to claim 1, wherein
the plurality of semiconductor chips includes semiconductor chips having different functions.

3. A semiconductor device comprising:
a semiconductor chip that has a surface on which a plurality of connection terminals is formed;
a first mounting board that includes:
a first surface on which the semiconductor chip is mounted by using the plurality of connection terminals; and
a second surface on which a plurality of connection terminals is formed;
a first frame that is seamlessly formed, on the first surface of the first mounting board, along an outer periphery of the semiconductor chip, the first frame enclosing the plurality of connection terminals formed on the semiconductor chip;
a first filler that fills the first frame;
a second mounting board that has a third surface on which the first mounting board is mounted by using the plurality of connection terminals formed on the second surface of the first mounting board;
a second frame that is seamlessly formed on the third surface of the second mounting board along an outer periphery of the first mounting board, the second frame enclosing the plurality of connection terminals formed on the first mounting board; and
a second filler that fills the second frame.

4. The semiconductor device according to claim 3, further comprising:
a plurality of semiconductor chips each of which has a surface on which a plurality of connection terminals is formed, wherein
the plurality of semiconductor chips is mounted on the first surface of the first mounting board.

5. The semiconductor device according to claim 3, wherein
each of the first filler and the second filler includes a thermosetting resin.

6. The semiconductor device according to claim 3, wherein
each of the first filler and the second filler includes a thermoplastic resin.

7. The semiconductor device according to claim 3, wherein
the semiconductor device is provided with a gap between the surface of the semiconductor chip and an upper surface of the first frame, the gap being filled with the first filler.

8. The semiconductor device according to claim 3, wherein
the semiconductor device is provided with a gap between the second surface of the first mounting board and an upper surface of the second frame, the gap being filled with the second filler.

9. The semiconductor device according to claim 3, wherein
the first frame includes a portion that extends toward an outer side from the outer periphery of the surface of the semiconductor chip.

10. The semiconductor device according to claim 3, wherein
the first frame has an outer-peripheral shape that coincides with an outer-peripheral shape of the surface of the semiconductor chip.

11. The semiconductor device according to claim 3, wherein
a thickness of the second mounting board is larger than that of the first mounting board.

12. The semiconductor device according to claim 3, wherein
the second mounting board has a linear expansion coefficient that is larger than that of the first mounting board.

13. A manufacturing method of a semiconductor device, the method comprising:
preparing a semiconductor chip having a surface on which a plurality of connection terminals is formed;
preparing a first mounting board having a first surface on which a first frame is formed;
mounting, by using the plurality of connection terminals, the semiconductor chip on the first surface of the first mounting board so that the plurality of connection terminals is positioned in the first frame;
filling the first frame with a first filler;
forming a plurality of connection terminals on a second surface of the first mounting board, the second surface being opposite to the first surface;
preparing a second mounting board having a second surface on which a second frame is formed;
mounting, by using the plurality of connection terminals formed on the first mounting board, the first mounting board on the surface of the second mounting board so that the plurality of connection terminals formed on the first mounting board is positioned in the second frame; and
filling the second frame with a second filler.

14. The manufacturing method of the semiconductor device according to claim 13, wherein
each of the first filler and the second filler includes a thermosetting resin.

15. The manufacturing method of the semiconductor device according to claim 14, the method further comprising:
curing the first filler after having filled the first frame with the first filler.

16. The manufacturing method of the semiconductor device according to claim 13, wherein
each of the first filler and the second filler includes a thermoplastic resin.

17. The manufacturing method of the semiconductor device according to claim 16, wherein
the mounting the semiconductor chip on the first surface of the first mounting board is executed after having filled the first frame with the first filler.

18. The manufacturing method of the semiconductor device according to claim 13, wherein
the second mounting board has a linear expansion coefficient that is larger than that of the first mounting board.

19. The manufacturing method of the semiconductor device according to claim 13, wherein
a thickness of the second mounting board is larger than that of the first mounting board.

20. The manufacturing method of the semiconductor device according to claim 13, wherein
the preparing a semiconductor chip includes preparing a plurality of semiconductor chips having different functions, each of the plurality of semiconductor chips having a surface on which a plurality of connection terminals is formed;
the preparing a first mounting board includes preparing the first mounting board on which a plurality of first frames including the first frame is formed, the plurality of first frames corresponding to the respective plurality of semiconductor chips; and
the mounting the semiconductor chip on the first surface of the first mounting board includes mounting the plurality of semiconductor chips so that each of the plurality of semiconductor chips is positioned in the corresponding first frame.
